(19) United States
(12) Patent Application Publication
(10) Pub. No.: US 2008/0072951 A1
(43) Pub. Date: Mar. 27, 2008

(54) INTERCONNECTED SOLAR CELLS

(75) Inventor: Andrew Mitchell Gabor, Providence, RI (US)

Correspondence Address: BROMBERG & SUNSTEIN LLP, 125 SUMMER STREET, BOSTON, MA, 02110-1618, US

(73) Assignee: Evergreen Solar, Inc., Marlborough, MA (US)

(21) Appl. No.: 11/848,791

(22) Filed: Aug. 31, 2007

Related U.S. Application Data
(60) Provisional application No. 60/841,735, filed on Sep. 1, 2006.

(51) Int. Cl. H01L 31/042; H01L 31/18

(52) U.S. Cl. 136/244

(57) ABSTRACT

Interconnected solar cells include a first solar cell and a second solar cell connected by a wire with a coefficient of thermal expansion matched to the first solar cell's coefficient of thermal expansion.

### CROSS-REFERENCE TO RELATED APPLICATION

This application claims the benefit of and priority to U.S. Provisional Patent Application Ser. No. 60/841,735 filed Sep. 1, 2006, which is owned by the assignee of the instant application and the disclosure of which is incorporated herein by reference in its entirety.

### FIELD OF THE INVENTION

The invention relates generally to interconnected solar cells. In particular, the invention relates to methods for connecting solar cells.

### BACKGROUND OF THE INVENTION

Manufacturing cost and yield are critical to producing economical solar cell modules. Solar cells are generally connected with a flat wire (e.g., a tab) soldered onto the solar cell. Solder coated copper is generally utilized by the solar cell industry in connecting silicon solar cells. However, connecting solar cells can have undesirable side effects. As a result of its higher coefficient of thermal expansion, copper wire contracts much more than the solar cell upon cooling from soldering.

In the case of ribbon solar cells, differential contraction can increase manufacturing cost and reduce yield by cracking solar cells during the connection. Of greater concern, differential contraction can form microscopic cracks in the solar cell, which can enlarge when the solar cells are stressed, and can ultimately form macroscopic cracks (e.g., a cracked cell). Cracking can cause long term problems including reduced reliability, mechanical failure, and power decay.

### SUMMARY OF THE INVENTION

The invention, in various embodiments, features methods and apparatus for connecting solar cells. A wire's coefficient of thermal expansion (CTE) can be matched to a solar cell's CTE, which can mitigate cracking of the solar cell after connection to the wire. Advantages of the invention include: increased yield, reduced cost, reduced degradation, reduced cracking, reduced power loss, and higher reliability for interconnected solar cells.

In various aspects, the invention features interconnected solar cells including a first solar cell and a second solar cell connected by a wire. The wire includes (i) a first material with a coefficient of thermal expansion about equal to the first solar cell's coefficient of thermal expansion and (ii) a conductive material for facilitating electrical current flow between the first solar cell and the second solar cell.

In one aspect, the invention features interconnected solar cells including a first solar cell and a second solar cell connected by a wire. The solar cells each include a silicon wafer that has a thickness of less than about 300 microns. The wire includes (i) a first material with a coefficient of thermal expansion about equal to the first solar cell's coefficient of thermal expansion and (ii) a conductive material for facilitating electrical current flow between the first solar cell and the second solar cell.

In another aspect, the invention features a method for forming interconnected solar cells. The method includes providing a first solar cell, disposing a second solar cell adjacent the first solar cell, and connecting the two solar cells with a wire. The solar cells each include a silicon wafer that is less than about 300 microns thick. The wire includes (i) a first material having a coefficient of thermal expansion about equal to the first solar cell's coefficient of thermal expansion and (ii) a conductive material for facilitating electrical current flow between the first solar cell and the second solar cell.

In yet another aspect, the invention features interconnected solar cells. The interconnected solar cells include a first semiconductor wafer and a second semiconductor wafer, each less than about 300 microns thick. The first and second semiconductor wafers are connected by a wire, which includes a first material having a coefficient of thermal expansion about equal to the first semiconductor wafer's coefficient of thermal expansion. The wire also includes a conductive material for facilitating electrical communication between the first semiconductor wafer and the second semiconductor wafer.

In still another aspect, the invention features a method for forming interconnected solar cells. The method includes providing a first semiconductor wafer, disposing a second semiconductor wafer adjacent the first semiconductor wafer, and connecting the two semiconductor wafers with a wire. The first semiconductor wafer and the second semiconductor wafer are less than about 300 microns thick. The wire includes (i) a first material having a coefficient of thermal expansion about equal to the first semiconductor wafer's coefficient of thermal expansion and (ii) a conductive material for facilitating electrical communication between the first semiconductor wafer and the second semiconductor wafer.

In still yet another example, the invention features interconnected solar cells. The interconnected solar cells include a first solar cell and a second solar cell and a wire connecting the first solar cell and the second solar cell. The wire includes a first material having a coefficient of thermal expansion about equal to the first solar cell's coefficient of thermal expansion and a conductive material for facilitating electrical current flow between the first solar cell and the second solar cell.

In other examples, any of the aspects above, or any apparatus or method described herein, can include one or more of the following features.

In various embodiments, the silicon wafer or semiconductor wafer is characterized by a thickness of between about 50 microns and about 200 microns. The first solar cell can include ribbon silicon. In some embodiments, the conductive material is copper or aluminum. In some embodiments, the wire includes a nickel iron alloy. The wire can be a copper-invar composite. The wire can include about 30% to about 90% copper by volume. The copper-invar composite can have a ratio of about 50% copper to about 50% invar by volume.

In various embodiments, the method includes soldering the wire to the first solar cell and soldering the wire to the second solar cell to electrically connect the first solar cell and the second solar cell to form the interconnected solar cells. In some embodiments, the method includes matching the first coefficient of thermal expansion and a coefficient of thermal expansion of the wire to mitigate cracking the first solar cell upon soldering and cooling of the wire and the first solar cell.

Other aspects and advantages of the invention will become apparent from the following drawings and description, all of which illustrate principles of the invention, by way of example only.

### BRIEF DESCRIPTION OF THE DRAWINGS

The advantages of the invention described above, together with further advantages, may be better understood by referring to the following description taken in conjunction with the accompanying drawings. The drawings are not necessarily to scale, emphasis instead generally being placed upon illustrating the principles of the invention.

FIGS. 1A and 1B show alternative views of exemplary interconnected solar cells.

FIG. 2A shows an exemplary cracked solar cell.

FIG. 2B shows an exemplary model for cracking.

FIG. 3 shows exemplary power degradation as a function of number of cracked solar cells.

FIG. 4 shows a cross section of an exemplary wire.

FIG. 5 shows a cross section of another exemplary wire.

FIG. 6 shows a cross section of yet another exemplary wire.

FIG. 7 shows a thermal expansion profile of an exemplary wire.

FIG. 8 shows a composite wire.

FIG. 9 shows exemplary cracking of solar cells.

FIG. 10 shows an exemplary technique for forming interconnected solar cells.

### DETAILED DESCRIPTION OF THE INVENTION

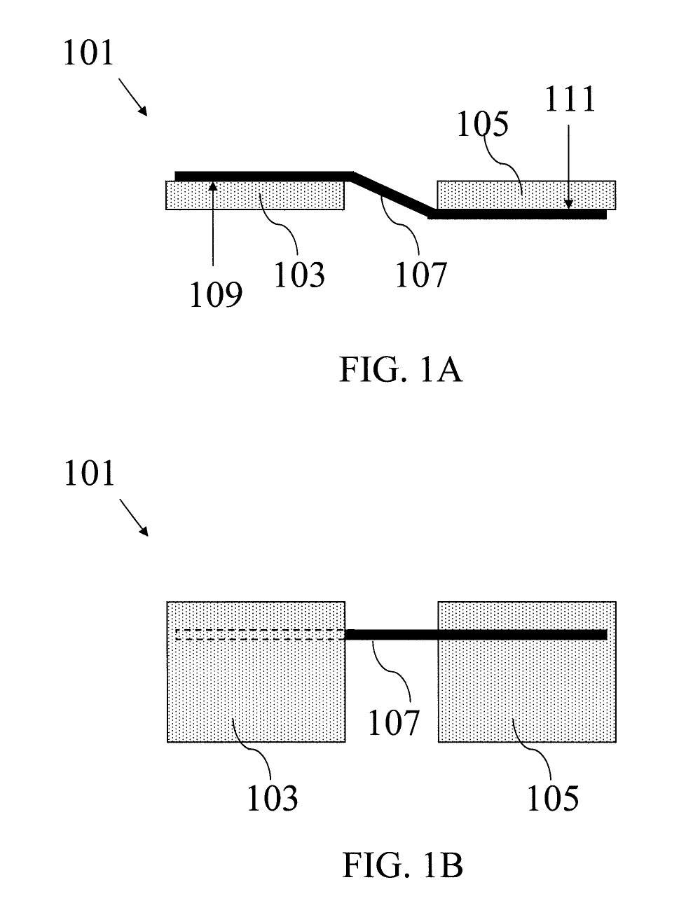

FIG. 1A shows an exemplary side view of interconnected solar cells 101 including a first solar cell 103, a second solar cell 105, and a wire 107. The wire connects a first surface 109 of the first solar cell 103 and a second surface 111 of the second solar cell 105. FIG. 1B shows an exemplary top view of the interconnected solar cells 101. The coefficient of thermal expansion (CTE) of the wire 107 can be matched to the CTE of one or both of the solar cells 103, 105. This can mitigate cracking of a solar cell 103, 105 after connection to the wire 107.

A solar cell can include a semiconductor wafer, a front metallization layer, and/or a back metallization layer. The semiconductor wafer can be a silicon wafer. The semiconductor wafer can have a thickness of less than about 300 microns. In some embodiments, the semiconductor wafer is between about 50 microns and about 200 microns thick. In certain embodiments, the semiconductor wafer is between about 50 and about 100 microns thick. In certain other embodiments, the semiconductor wafer is between about 100 and about 200 microns thick. In one embodiment, the semiconductor wafer is about 150 microns thick. In one embodiment, the semiconductor wafer is about 80 microns thick.

In certain embodiments, the solar cell includes silicon. The silicon can be doped by materials including boron. A dopant and/or amount of dopant can be chosen to achieve a desired resistivity. In some embodiments, the solar cell can include a Group IV element, such as germanium.

In some embodiments, a solar cell can include ribbon silicon, which can be formed by a STRING RIBBON™ technique. In the STRING RIBBON™ technique, two high temperature strings are pulled vertically through a shallow silicon melt, and the molten silicon spans and freezes between the strings. The process is continuous: long strings are unwound from spools; the melt is replenished; and the silicon ribbon is cut to length for further processing, without interrupting growth. This advantage in material efficiency means a STRING RIBBON™ technique yields over twice as many solar cells per pound of silicon as conventional methods. Additionally, the resulting distinctive shape of the solar cell allows for a high packing density.

In various embodiments, two or more interconnected solar cells can be laminated to form a solar cell module. In some embodiments, interconnected solar cells can be laminated between a glass layer and a plastic layer. In certain embodiments, the laminated, interconnected solar cells can be framed. The frame can be aluminum or extruded aluminum.

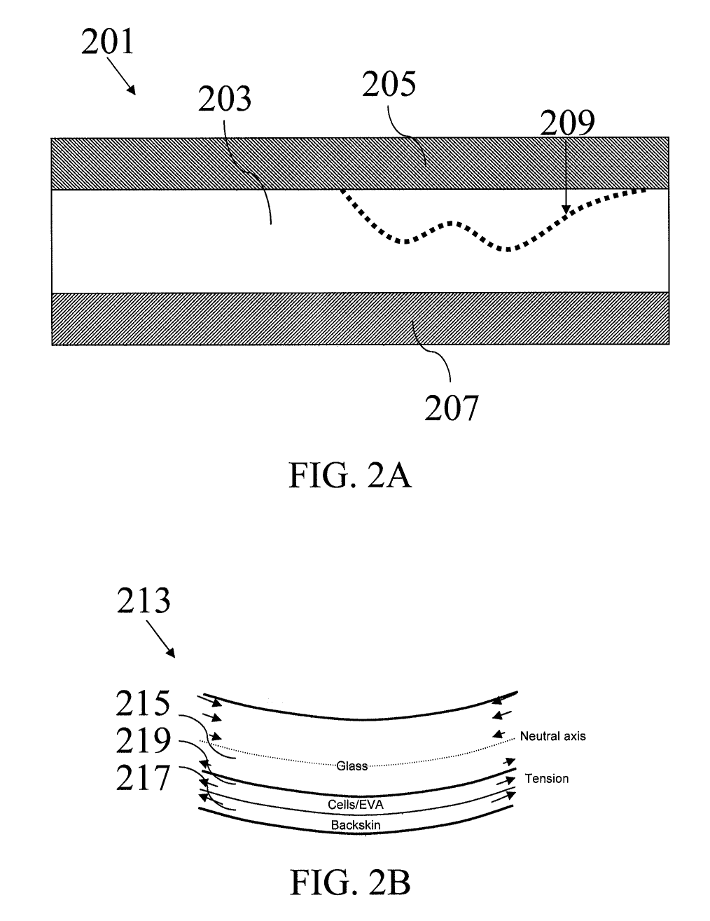

FIG. 2A shows an interconnected solar cell 201 including a solar cell 203, a first copper wire 205, and a second copper wire 207. The interconnected solar cell 201 includes a first crack 209 formed proximally to the point of soldering of the first copper wire 205. Soldering to connect the first and second copper wires 205, 207 to the solar cell 203 raises the temperature of each component. Because the first and second copper wires 205, 207 have a higher CTE than the solar cell 203, the first and second copper wires 205, 207 contract more than the solar cell 203 upon cooling. The different rates of contraction upon cooling can form cracks, and/or micro cracks in the solar cell, and reduce manufacturing yield.

FIG. 2B also shows an exemplary model for cracking of a solar cell within a solar cell module 213. A glass layer 215 and a backskin layer 217 encapsulate the solar cell 219 to form the solar cell module 213. Applying force to the encapsulated solar cell module 213 can simulate stress to which the solar cell module 213 is exposed during use (e.g., wind, rain, snow, and ice). Stress can form cracks, macroscopic cracks, and/or cracked cells, resulting in problems including solar cell failures and/or power degradation.

In solar cells including a semiconductor wafer of thickness greater than about 300 microns, the difference in CTE between the solar cell (e.g., silicon) and the wire (e.g., copper) does necessarily not cause problematic or macroscopic cracking. However, in solar cells including a semiconductor wafer characterized by a thickness less than about 300 microns, stress caused by thermal contraction of the wire upon soldering and cooling can induce cracking and/or microscopic cracks, which can cause problematic or macroscopic cracking.

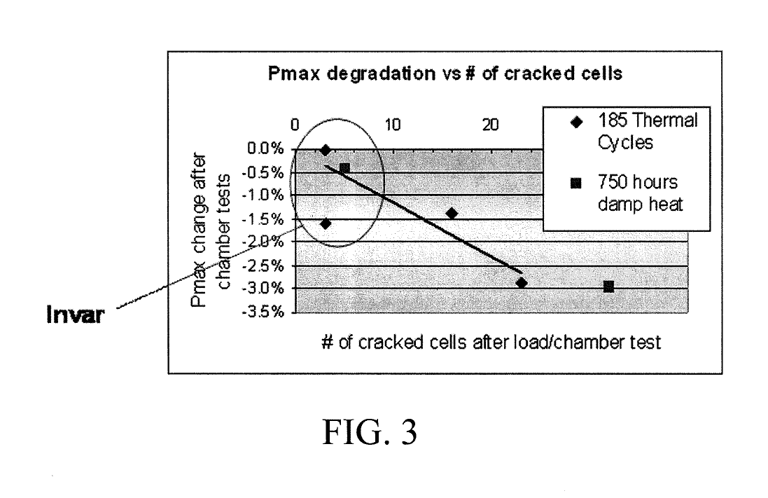

FIG. 3 shows exemplary maximum power (Pmax) degradation as a function of number of cracked solar cells. Table 1 (below) tabulates the data plotted in FIG. 3. The tested modules include wire of copper or copper clad Invar composite. The copper wire was 75 microns thick, excluding solder. The Invar composite wire was 100 microns thick, excluding solder, and included about 50% Invar42 by volume. After interconnecting the solar cells with the two different wires, modules were constructed by encapsulating the interconnected solar cells in glass and plastic backsheet layers. Each module was stressed by loading bricks on the top surface. The power of each module was measured and recorded. Each module was then placed in a thermal cycling chamber and a damp heat environmental chamber to simulate long term environmental exposure, after which the power of each module was again measured and recorded. Each type of wire was tested twice. Modules including Invar composite wires suffered fewer cracked solar cells and less power loss than the modules including copper wires.

TABLE 1
Solar cell module power degradation upon exposure to stress.

| Module | % change Pmax | Test |
|---|---|---|
| Cu1 | −2.9% | Damp heat |
| Cu2 | −1.4% | Thermal Cycle |
| Cu3 | −2.9% | Thermal Cycle |
| Invar1 | −0.4% | Damp heat |
| Invar2 | −1.6% | Thermal Cycle |
| Invar3 | 0.0% | Thermal Cycle |

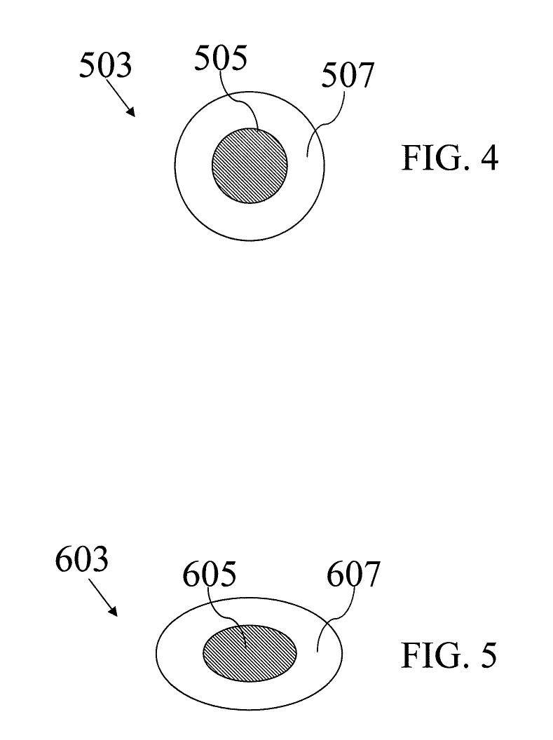

FIG. 4 shows a cross section of an exemplary composite wire 503 with a round cross section including an Invar core 505 and a copper cladding 507.

FIG. 5 shows a cross section of an exemplary composite wire 603 with an oval cross section including an Invar core 605 and a copper cladding 607.

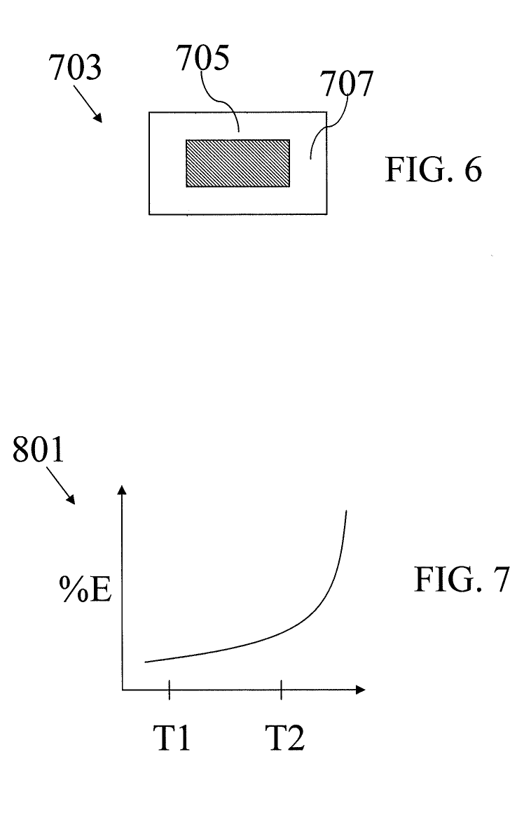

FIG. 6 shows a cross section of an exemplary composite wire 703 with a rectangular cross section including an Invar core 705 and a copper cladding 707.

Including copper in a composite wire facilitates electrical current flow between solar cells. However, copper's CTE is greater than silicon's CTE, which can cause cracking of the solar cell after soldering. Invar's CTE is about equal to, or lower than, silicon's CTE. Including Invar with copper in a composite wire can help match the CTE of the composite wire to the CTE of silicon, mitigating cracking of the solar cell after soldering.

In various embodiments, copper can be substituted by another conductive material (e.g., aluminum, gold, silver). In some embodiments, Invar can be substituted by another low CTE material (e.g., Kovar, Rodar, Havar, or Nilo). The copper and Invar can form a composite, but are not necessarily commingled. The wire can include about 30% to about 90% conductive material by volume. In one embodiment, the wire includes about 50% copper and about 50% Invar. Invar and copper clad Invar are readily available from a number of distributors, including Torpedo Specialty Wire, Inc. (Rocky Mount, N.C.) and Ulbrich Precision Flat Wire, LLC (Westminster, S.C.).

In some embodiments, the wire is flat, has width of about 1 mm to about 4 mm, and/or a thickness of about 75 to about 200 microns. Increasing a wire's copper content has the advantage of reducing resistive power loss, but the disadvantage of increasing CTE. Increasing a wire's Invar content has the advantage of decreasing CTE. However, increasing a wire's diameter (e.g., the amount of copper and/or Invar) has the disadvantage of increasing interconnected solar cell cost.

FIG. 7 shows a thermal expansion profile 801 of an exemplary wire. Composite wires according to the invention can have a CTE such that they do not have a large percent expansion (% E) when heating/cooling between about room temperature (T1) and about the temperature of soldering (T2). The CTE of the composite wire can be matched to about the CTE of the solar cell by modulating the amount of (i) the low CTE material (e.g., Invar) and (ii) the conductive material (e.g., copper).

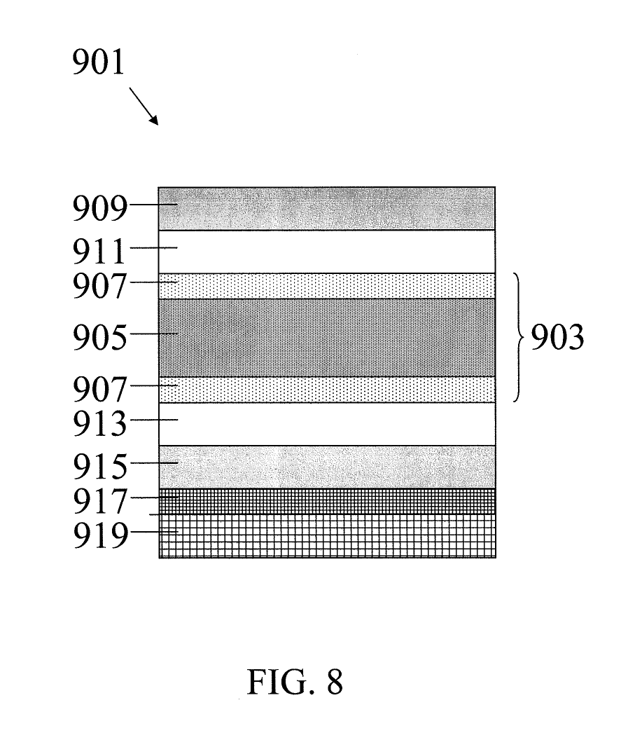

FIG. 8 shows a section of an interconnected solar cell 901 including a composite wire 903 with an Invar (e.g., Ni—Fe alloy) core 905 and copper cladding 907. Copper has a higher CTE (16.5 ppm/° C.) than silicon (2.6 ppm/° C.) and Invar has a lower CTE (2 ppm/° C. for Invar36) than silicon. The resulting composite wire has a CTE matched to about the CTE of the solar cell (e.g., silicon). Attaching a solar cell including a semiconductor wafer with a thickness of less than about 300 microns (e.g., about 50 to about 200 microns) with a composite wire according the invention can reduce cracking compared to traditional (e.g., copper or tin clad copper) wires.

The interconnected solar cell 901 also includes a first 909 epoxy layer, a top 911 solder layer, a bottom 913 solder layer, a second 915 epoxy layer, a front 917 Ag layer, and a silicon wafer 919.

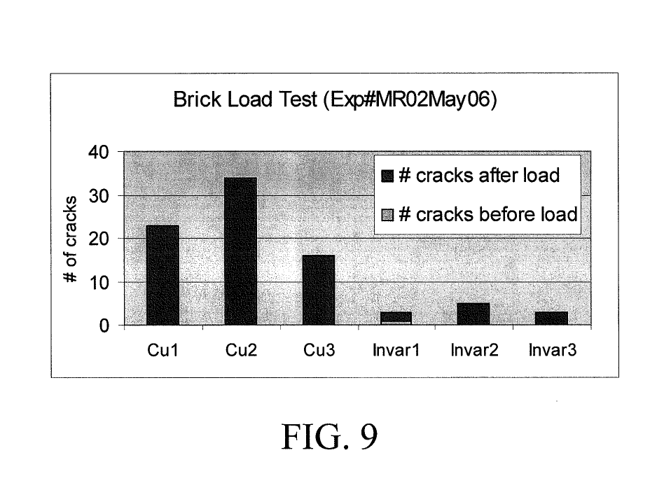

FIG. 9 shows exemplary cracking of encapsulated, aluminum framed solar cell modules before and after stress. Piling bricks across the face of each module caused the center, unsupported region of each module to sag. Cracks were counted by applying an electrical bias to the modules such that the cells emitted light in an electroluminescent mode. A video camera with a filter imaged the emitted light. Cracked regions appeared as dark lines or dark regions. Before stressing the solar cell modules, there were essentially no macroscopic cracks in either test set. After stressing the solar cell modules, the copper wire test set (Cu 1-3) develops about an order of magnitude more macroscopic cracks than the composite wire test set (Invar 1-3).

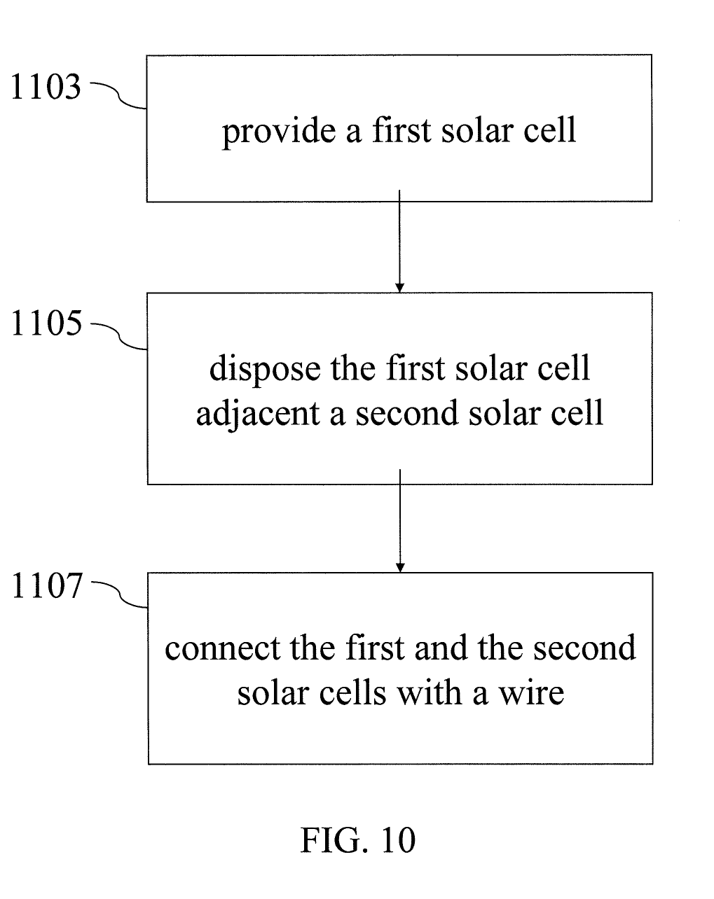

FIG. 10 shows a technique for forming an interconnected solar cell. The technique includes providing a first solar cell (step 1103), disposing a second solar cell adjacent the first solar cell (step 1105), and connecting the first and the second solar cells with a wire (step 1107). The first solar cell and the second solar cell can include a silicon wafer that is less than about 300 microns thick. The wire includes a first material having a coefficient of thermal expansion about equal to the first solar cell's coefficient of thermal expansion. The wire also includes a conductive material for facilitating electrical current flow between the first solar cell and the second solar cell.

In various embodiments, the wire is soldered to the first solar cell and the second solar cell to electrically connect the solar cells and form the interconnected solar cell. In some embodiments, the first coefficient of thermal expansion and a coefficient of thermal expansion of the wire are matched to mitigate cracking the first solar cell upon soldering and cooling of the wire and the first solar cell.

While the invention has been particularly shown and described with reference to specific embodiments, it should be understood by those skilled in the art that various changes in form and detail may be made without departing from the spirit and scope of the invention as defined by the appended claims.

1. Interconnected solar cells comprising:
a first solar cell including a first silicon wafer characterized by a thickness of less than about 300 microns;
a second solar cell including a second silicon wafer characterized by a thickness of less than about 300 microns; and
a wire connecting the first solar cell and the second solar cell, the wire comprising:
a first material having a coefficient of thermal expansion about equal to the first solar cell's coefficient of thermal expansion; and
a conductive material for facilitating electrical current flow between the first solar cell and the second solar cell.

2. The interconnected solar cells of claim 1 wherein the first silicon wafer is characterized by a thickness of between about 50 microns and about 200 microns.

3. The interconnected solar cells of claim 1 wherein the first solar cell comprises ribbon silicon.

4. The interconnected solar cells of claim 1 wherein the conductive material comprises copper.

5. The interconnected solar cells of claim 1 wherein the conductive material comprises aluminum.

6. The interconnected solar cells of claim 1 wherein the wire comprises a nickel iron alloy.

7. The interconnected solar cells of claim 1 wherein the wire comprises a copper-invar composite.

8. The interconnected solar cells of claim 1 wherein the wire comprises about 30% to about 90% copper by volume.

9. The interconnected solar cells of claim 1 wherein the wire comprises a ratio of about 50% copper to about 50% invar by volume.

10. A method for forming interconnected solar cells comprising:
providing a first solar cell including a first silicon wafer characterized by a thickness of less than about 300 microns and a first coefficient of thermal expansion;
disposing adjacent the first solar cell a second solar cell including a second silicon wafer characterized by a thickness of less than about 300 microns; and
connecting the first solar cell and the second solar cell with a wire, the wire comprising:
a first material having a coefficient of thermal expansion about equal to the first solar cell's coefficient of thermal expansion; and
a conductive material for facilitating electrical current flow between the first solar cell and the second solar cell.

11. The method of claim 9 further comprising:
soldering the wire to the first solar cell; and
soldering the wire to the second solar cell to electrically connect the first solar cell and the second solar cell to form the interconnected solar cells.

12. The method of claim 9 further comprising matching the first solar cell's coefficient of thermal expansion and a coefficient of thermal expansion of the wire to mitigate cracking the first solar cell upon soldering and cooling of the wire and the first solar cell.

13. Interconnected solar cells comprising:
a first solar cell and a second solar cell; and
a wire connecting the first solar cell and the second solar cell, the wire comprising:
a first material having a coefficient of thermal expansion about equal to the first solar cell's coefficient of thermal expansion; and
a conductive material for facilitating electrical current flow between the first solar cell and the second solar cell.

14. The interconnected solar cells of claim 13 wherein the first solar cell comprises ribbon silicon.

15. The interconnected solar cells of claim 13 wherein the conductive material comprises copper.

16. The interconnected solar cells of claim 13 wherein the conductive material comprises aluminum.

17. The interconnected solar cells of claim 13 wherein the wire comprises a nickel iron alloy.

18. The interconnected solar cells of claim 13 wherein the wire comprises a copper-invar composite.

19. The interconnected solar cells of claim 13 wherein the wire comprises about 30% to about 90% copper by volume.

20. The interconnected solar cells of claim 13 wherein the wire comprises a ratio of about 50% copper to about 50% invar by volume.
